(19) United States
(12) Patent Application Publication
(10) Pub. No.: US 2019/0382884 A1
(43) Pub. Date: Dec. 19, 2019

(54) EVAPORATION DEVICE AND EVAPORATION METHOD

(71) Applicant: SHENZHEN CHINA STAR OPTOELECTRONICS SEMICONDUCTOR DISPLAY TECHNOLOGY CO., LTD., Shenzhen, Guangdong (CN)

(72) Inventor: Yang LIU, Shenzhen, Guangdong (CN)

(21) Appl. No.: 15/742,831

(22) PCT Filed: Nov. 29, 2017
(86) PCT No.: PCT/CN2017/113669

§ 371 Date: Jan. 8, 2018

(30) Foreign Application Priority Data
Oct. 30, 2017 (CN) 201711038771.X

(51) Int. Cl. C23C 14/54; C23C 14/24

(52) U.S. Cl. CPC C23C 14/546; C23C 14/243

(57) ABSTRACT

The disclosure provides an evaporation device and an evaporation method. The evaporation device of the disclosure configures an crystal shutter between an evaporation source and a crystal vibrator, and the crystal shutter is capable of switching between the position that the crystal vibrator is shielded and the position that the crystal vibrator is not shielded; an evaporation material is deposited on the crystal shutter when the crystal shutter is at the position that the crystal vibrator is shielded, thereby avoiding the evaporation material deposited on the crystal vibrator: the evaporation material may be deposited on the crystal vibrator when the crystal shutter is at the position that the crystal vibrator is not shielded.

### RELATED APPLICATIONS

The present application is a National Phase of International Application Number PCT/CN2017/113669, filed on Nov. 29, 2017, and claims the priority of China Application 201711038771.X, filed on Oct. 30, 2017.

### FIELD OF THE DISCLOSURE

The disclosure relates to the field of display technology, and particularly to an evaporation device and an evaporation method.

### BACKGROUND

Vacuum evaporation is an important film-forming technique widely used in displays, electronic circuits, optics, molds and other industrial fields. For example; in organic light emitting diode (OLED) display technology, film-forming of organic materials and metals materials is made by vacuum evaporation to produce OLED elements and devices.

The essential process of evaporation is as follows: an evaporation material is placed into the crucible of an evaporation chamber; after the chamber is evacuated to a certain degree of vacuum (E⁻⁵ Pa), the crucible is heated to make the evaporation material reach a certain temperature; the gas molecules of the evaporation material sprayed from the crucible are deposited on a substrate to form a target film, and also on a crystal vibrator of an evaporation rate monitoring device. The evaporation rate monitoring device monitors the evaporation rate and thickness of the target film by monitoring the evaporation rate of the material film deposited on the crystal vibrator.

The evaporation rate monitoring can be achieved by the crystal vibrator because the thickness of the material film deposited on the crystal vibrator and the attenuation of the vibration frequency of the crystal vibrator have following relationship;

$$Δ f = - \frac{{ρ}_{m}}{{ρ}_{q}} \cdot \frac{{f}^{2}}{N} Δ {d}_{m} ;$$

wherein f is the initial vibration frequency of the crystal vibrator (fixed value for a fixed type of the crystal vibrator), N is the vibration frequency constant, ρₘ is the density of the evaporation material film layer, and ρ_{q} is the density of the crystal vibrator (fixed value); the changing value Δf of the vibration frequency of the crystal vibrator and the changing value Δdₘ of the thickness of the evaporation material film have a proportional relationship, i.e. after setting the density of a kind of evaporation material in the evaporation rate monitoring device, evaporation rate of this material may be monitored by monitoring changes in the vibration frequency of the crystal vibrator.

However, since active metal materials such as lithium (Li), potassium (K), calcium (Ca), magnesium (Mg), ytterbium (Yb), barium (Ba) and the like are easily oxidized or nitrided, the surface of such materials often forms oxides or nitrides, making evaporation rate control more difficult in an evaporation process before the oxides or nitrides is completely removed. For example, the evaporation of white organic light-emitting diode (WOLED) elements requires the use of metal Li as a electron injection material. Although the metal Li is under the protection of an inert gas (e.g. argon) during production and storage to avoid being oxidized or nitrided, a small amount of the metal Li will be still oxidized and nitrided to form lithium oxide (Li₂O) and lithium nitride (Li₃N) while feeding towards the evaporation crucible and evacuating the chamber. After heating for a certain period, Li₂O and Li₃N will be evaporated and deposited on the crystal vibrator of the evaporation rate monitoring device. The densities of Li₂O, Li₃N and Li are different, but because the evaporation rate monitoring device calculates evaporation rate based on density of Li, so the following situation will occur, i.e. the evaporation rate monitoring is unstable and the evaporation rate is false.

FIG. 1 is a curve of the evaporation rate of lithium (Li) monitored by the evaporation rate monitoring device in prior evaporation process. As shown in FIG. 1, since Li₂O and Li₃N are also evaporated on the crystal vibrator of the evaporation rate monitoring device, the evaporation rate of Li monitored by the evaporation rate monitoring device is fluctuated relatively largely, and monitoring effect of the evaporation rate is poor.

### SUMMARY

An objective of the disclosure is to provide an evaporation device, which can ensure that influences of the surface impurities of the material to be evaporated on the monitor of an evaporation rate can be avoided during an evaporation process, and allow the evaporation rate monitoring device to obtain the steady evaporation rate

An objective of the disclosure is also to provide an evaporation method, and the evaporation method may be achieved by the above evaporation device; and can ensure that influences of the surface impurities of the material to be evaporated on the monitor of an evaporation rate can be avoided during an evaporation process, and allow the evaporation rate monitoring device to obtain the steady evaporation rate.

In order to achieve the above objectives; the disclosure provides an evaporation device, including: a chamber, an evaporation source disposed in the chamber, a film substrate to be evaporated disposed in the chamber and located over the evaporation source, and an evaporation rate monitoring device disposed in the chamber and located over the evaporation source:

the evaporation rate monitoring device includes a crystal vibrator; and the crystal vibrator is a probe of the evaporation rate monitoring device, and the evaporation rate monitoring device monitors evaporation rate of a material film layer deposited on the crystal vibrator and then calculates so as to obtain the evaporation rate of a target film layer deposited on the film substrate to be evaporated:

the evaporation device further includes a crystal shutter disposed at any positions between the evaporation source and the crystal vibrator, and the crystal shutter is capable of switching between the position that the crystal vibrator is shielded and the position that the crystal vibrator is not shielded.

The evaporation device further includes a source shutter disposed over the evaporation source, and the source shutter is capable of switching between the position that the evaporation source is shielded and the position that the evaporation source is not shielded;

the evaporation source includes a crucible and a material to be evaporated placed within the crucible;

the crystal vibrator is quartz crystal vibrator;

the crystal shutter is located close to the crystal vibrator between the evaporation source and the crystal vibrator, close to the evaporation source between the evaporation source and the crystal vibrator, or in the middle position between the crystal vibrator and the evaporation source.

The crystal shutter is located close to the crystal vibrator between the evaporation source and the crystal vibrator.

The diameter of the crystal shutter of the crystal vibrator is greater than the diameter of an area of the film to be evaporated of the crystal vibrator.

The crystal shutter is made of metal materials, and the metal materials include one or more of stainless steel, aluminum, and titanium.

The crystal shutter has a surface roughening treated surface disposed at one side facing the evaporation source, and the surface roughening treatment includes one or more of shot peening, sand blasting, and aluminum spray treatment.

The specific structure of the evaporation rate monitoring device includes: a crystal vibrator shielding cartridge, a crystal vibrator base sleeve disposed in the crystal vibrator shielding cartridge, a crystal vibrator base disposed in the crystal vibrator base sleeve, and a plurality of the crystal vibrators mounted on the crystal vibrator base, and an opening is disposed on the crystal vibrator base sleeve, and the crystal vibrators being used are present at the opening of the crystal vibrator base sleeve, and the crystal vibrators not being used are absent from the opening, and the crystal vibrator being used is switched to another crystal vibrator until the end of its service life;

the crystal shutter is located within the crystal vibrator shielding cartridge:

the crystal shutter locating at the position that the crystal vibrator is shielded means that the crystal shutter is located at the opening and shields the crystal vibrator being used; the crystal shutter locating at the position that the crystal vibrator is not shielded means that the crystal shutter is not located at the opening and does not shield the crystal vibrator being used.

The evaporation device further includes an actuation mechanism connected to the crystal shutter; the actuation mechanism enables the crystal shutter to revolve, so that the crystal shutter switches between the position that the crystal vibrator is shielded and the position that the crystal vibrator is not shielded.

The disclosure also provides an evaporation method, including the following steps:

step S1, providing the evaporation device according to claim 1, and in the evaporation device, the evaporation source including a crucible and a material to be evaporated placed within the crucible, and heating the crucible to a first evaporation temperature, and the surface impurities of the material to be evaporated being evaporated at the first evaporation temperature;

maintaining the first evaporation temperature for a period of time so that all the surface impurities of the material to be evaporated 215 being evaporated off;

in the step S1, evaporation materials being not deposited on the film substrate to be evaporated:

and, in the step S1, the crystal shutter being at the position that the crystal vibrator is shielded, and the impurities evaporated from the surface of the material to be evaporated being deposited on the crystal shutter, avoiding the surface impurities of the material to be evaporated deposited on the crystal vibrator;

step S2, heating the crucible to a second evaporation temperature, and materials inside the material to be evaporated being evaporated out at the second evaporation temperature, and being deposited on the film substrate to be evaporated at a target evaporation rate so as to form the target film layer;

in the step S2, the crystal shutter being at the position that the crystal vibrator is not shielded, and the materials evaporated from inside the material to be evaporated 215 being deposited on the crystal vibrator, and the evaporation rate monitoring device monitoring an evaporation rate of a material film layer deposited on the crystal vibrator and calculating to obtain the evaporation rate of the target film layer deposited on the film substrate to be evaporated.

In the step S1, before heating the crucible, the chamber is firstly evacuated to a desired degree of vacuum; the material to be evaporated is active metal materials, and the surface impurities of the material to be evaporated are oxides and/or nitrides of the active metal materials; the active metal materials include one or more of lithium, potassium, calcium, magnesium, ytterbium and barium.

The disclosure also provides an evaporation device; including: a chamber; an evaporation source disposed in the chamber, a film substrate to be evaporated disposed in the chamber and located over the evaporation source; and an evaporation rate monitoring device disposed in the chamber and located over the evaporation source;

The evaporation rate monitoring device includes a crystal vibrator; and the crystal vibrator is a probe of the evaporation rate monitoring device, and the evaporation rate monitoring device monitors evaporation rate of a material film layer deposited on the crystal vibrator and then calculates so as to obtain the evaporation rate of a target film layer deposited on the film substrate to be evaporated;

the evaporation device further includes a crystal shutter disposed at any positions between the evaporation source and the crystal vibrator, and the crystal shutter is capable of switching between the position that the crystal vibrator is shielded and the position that the crystal vibrator is not shielded;

further includes a source shutter disposed over the evaporation source, and the source shutter is capable of switching between the position that the evaporation source is shielded and the position that the evaporation source is not shielded;

the evaporation source includes a crucible and a material to be evaporated placed within the crucible;

the crystal vibrator is quartz crystal vibrator;

the crystal shutter is located close to the crystal vibrator between the evaporation source and the crystal vibrator, close to the evaporation source between the evaporation source and the crystal vibrator; or in the middle position between the crystal vibrator and the evaporation source;

wherein, the diameter of the crystal shutter of the crystal vibrator is greater than the diameter of an area of the film to be evaporated of the crystal vibrator;

wherein, the crystal shutter is made of metal materials, and the metal materials include one or more of stainless steel; aluminum, and titanium;

wherein, the crystal shutter has a surface roughening treated surface disposed at one side facing the evaporation source, and the surface roughening treatment includes one or more of shot peening, sand blasting, and aluminum spray treatment.

The advantageous effects of the disclosure: the evaporation device of the disclosure configures an crystal shutter between an evaporation source and a crystal vibrator, and the crystal shutter is capable of switching between the position that the crystal vibrator is shielded and the position that the crystal vibrator is not shielded; an evaporation material is deposited on the crystal shutter when the crystal shutter is at the position that the crystal vibrator is shielded, thereby avoiding the evaporation material deposited on the crystal vibrator; the evaporation material may be deposited on the crystal vibrator when the crystal shutter is at the position that the crystal vibrator is not shielded; when the evaporation device of the disclosure is applied to an evaporation process, at the initial stage of evaporation, namely the stage in which surface impurities of an material to be evaporated are evaporated, the crystal shutter is at the position that the crystal vibrator is shielded and the impurities are prevented from being deposited on the surface of the crystal vibrator; after the evaporation of the surface impurities of the material to be evaporated are finished, the crystal shutter is at the position that the crystal vibrator is not shielded, and the evaporation material is deposited on the surface of the crystal vibrator, and the evaporation rate monitoring device obtains a steady evaporation rate, and the thickness of a target film layer deposited on the film substrate to be evaporated may be monitored according to the evaporation rate. The evaporation method of the disclosure may be achieved by the above evaporation device, and can ensure that influences of the surface impurities of the material to be evaporated on the monitor of an evaporation rate can be avoided during an evaporation process, and allow the evaporation rate monitoring device to obtain the steady evaporation rate, and the thickness of the target film layer deposited on the film substrate to be evaporated may be real time and effectively monitored according to the evaporation rate.

In order to further understand the features and technical contents of the disclosure, the following detailed descriptions and appended drawings of the disclosure are hereby referred. However, the appended drawings are merely provided for reference and illustration, without any intention to be used for limiting the disclosure.

### BRIEF DESCRIPTION OF THE DRAWINGS

The technical solution and other advantageous effects will become apparent by the detailed description of the specific embodiments of the disclosure in conjunction with the appended drawings, in which,

FIG. 1 is a curve of the evaporation rate of metal lithium monitored by the evaporation rate monitoring device in prior evaporation process;

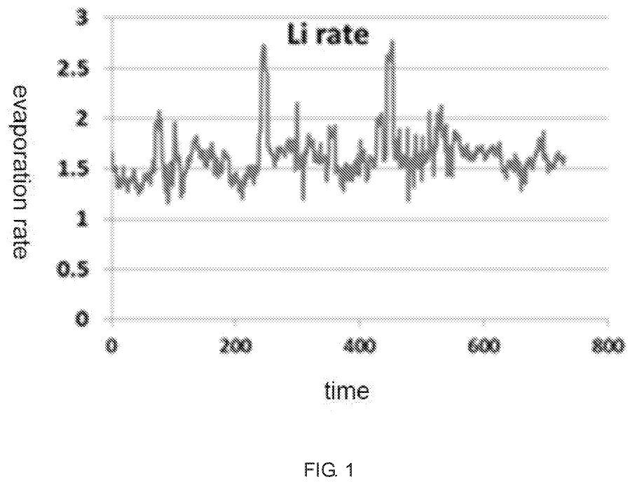

FIG. 2 is a structural schematic view of the evaporation device of the disclosure;

FIG. 3 is a detailed schematic view of dot-lined circle in FIG. 2;

FIG. 4 is a bottom view of FIG. 3;

FIG. 5 is a flow chart of the evaporation method of the disclosure;

FIG. 6 is a curve of the evaporation rate monitored by the evaporation rate monitoring device in step S2 in the evaporation method of the disclosure.

### DETAILED DESCRIPTION OF PREFERRED EMBODIMENTS

In order to further illustrate the technical means used in the disclosure and the effect thereof, the description is made below in detail in combination with the preferred embodiments of the disclosure and the appended drawings.

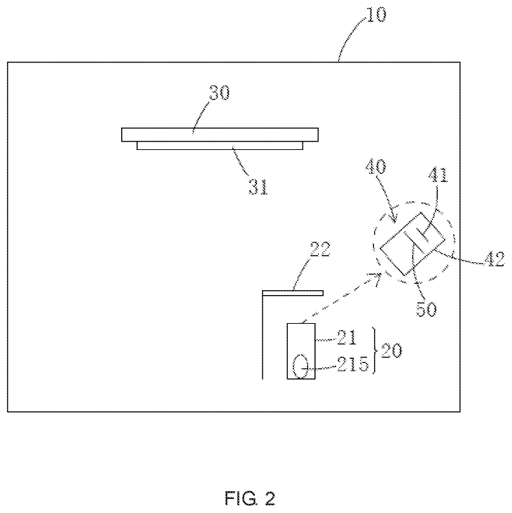

With reference to FIG. 2 to FIG. 4, the disclosure firstly provides a evaporation device, including: a chamber 10, an evaporation source 20 disposed in the chamber 10, a film substrate to be evaporated 30 disposed in the chamber 10 and located over the evaporation source 20, and an evaporation rate monitoring device 40 disposed in the chamber 10 and located over the evaporation source 20;

The evaporation rate monitoring device 40 includes a crystal vibrator 41; and the crystal vibrator 41 is a probe of the evaporation rate monitoring device 40, and the evaporation rate monitoring device 40 monitors the evaporation rate of a material film layer deposited on the crystal vibrator 41 and then calculates so as to obtain the evaporation rate of a target film layer 31 deposited on the film substrate to be evaporated 30:

The evaporation device further includes a crystal shutter 50 disposed at any positions between the evaporation source 20 and the crystal vibrator 41, and the crystal shutter 50 is capable of switching between the position that the crystal vibrator 41 is shielded and the position that the crystal vibrator 41 is not shielded. An evaporation material is deposited on the crystal shutter 50 when the crystal shutter 50 is at the position that the crystal vibrator 41 is shielded, thereby avoiding the evaporation material deposited on the crystal vibrator 41; the evaporation material may be deposited on the crystal vibrator 41 when the crystal shutter 50 is at the position that the crystal vibrator 41 is not shielded.

Specifically, in the horizontal direction, the evaporation rate monitoring device 40 is located in a peripheral area of the film substrate to be evaporated 30, thereby avoiding the influence on the deposition of the target film layer 31; in the vertical direction, the evaporation rate monitoring device 40 is located between the evaporation source 20 and the film substrate to be evaporated 30, and the evaporation rate monitoring device 40 is not far away from the evaporation source 2, so that the evaporation rate monitoring device 40 can achieve better monitoring effect.

Specifically, the evaporation device further includes a source shutter 22 disposed over the evaporation source 20, and the source shutter 22 is capable of switching between the position that the evaporation source 20 is shielded and the position that the evaporation source 20 is not shielded. The evaporation material can be deposited on the film substrate to be evaporated 30 when the source shutter 22 is at the position that the evaporation source 20 is not shielded; the evaporation material can not be deposited on the film substrate to be evaporated 30 when the source shutter 22 is at the position that the evaporation source 20 is shielded. Namely, the source shutter 22 serves to shield the evaporation source 20 instead of the crystal vibrator 41, and thus the source shutter 22 and the crystal shutter 50 have different functions.

Specifically, the evaporation source 20 includes a crucible 21 and a material to be evaporated 215 placed within the crucible 21.

Specifically, the crystal vibrator 41 is quartz crystal vibrator.

Specifically, the crystal shutter 50 may be located close to the crystal vibrator 41 between the evaporation source 20 and the crystal vibrator 41, close to the evaporation source 20 between the evaporation source 20 and the crystal vibrator 41, or in the middle position between the crystal vibrator 41 and the evaporation source 20.

Preferably, as shown in FIG. 2, the crystal shutter 50 is located close to the crystal vibrator 41 between the evaporation source 20 and the crystal vibrator 41. The advantages of such configuration is that the crystal shutter 50 may have a smaller diameter, save materials and have compact structure; if the crystal shutter 50 is located close to the evaporation source 20 or in the middle position between the evaporation source 20 and the crystal vibrator 41, the crystal shutter 50 will be required to have a larger diameter, and may pose spatial interference with the source shutter 22.

Specifically, the diameter of the crystal shutter 50 of the crystal vibrator is greater than the diameter of an area of the film to be evaporated of the crystal vibrator 41. Preferably, the diameter of the crystal shutter 50 of the crystal vibrator is greater than the diameter of the crystal vibrator 41 so as to achieve better shielding effect.

Specifically, the crystal shutter 50 is made of metal materials, and the metal materials include one or more of stainless steel, aluminum (Al), and titanium (Ti).

Specifically, the crystal shutter 50 has a surface roughening treated surface disposed at one side facing the evaporation source 20, and the surface roughening treatment includes one or more of shot peening, sand blasting, and aluminum (Al) spray treatment. The surface roughening treatment can enhance adhesiveness of the evaporation material to the surface of the crystal shutter 50.

Specifically, as shown in FIG. 2 to FIG. 4, the specific structure of the evaporation rate monitoring device 40 includes: a crystal vibrator shielding cartridge 42, a crystal vibrator base sleeve 43 disposed in the crystal vibrator shielding cartridge 42, a crystal vibrator base 44 disposed in the crystal vibrator base sleeve 43, and a plurality of the crystal vibrators 41 mounted on the crystal vibrator base 44, and an opening 431 is disposed on the crystal vibrator base sleeve 43, and the crystal vibrators 41 being used are present at the opening 431 of the crystal vibrator base sleeve 43, and the crystal vibrators 41 not being used are absent from the opening 431, and the crystal vibrator 41 being used is switched to another crystal vibrator 41 until the end of its service life;

the crystal shutter 50 is located within the crystal vibrator shielding cartridge 42;

the crystal shutter 50 locating at the position that the crystal vibrator 41 is shielded means that the crystal shutter 50 is located at the opening 431 and shields the crystal vibrator 41 being used; the crystal shutter 50 locating at the position that the crystal vibrator 41 is not shielded means that the crystal shutter 50 is not located at the opening 431 and does not shield the crystal vibrator 41 being used.

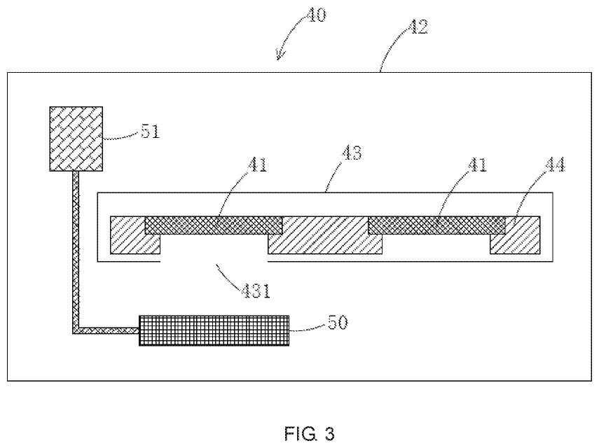

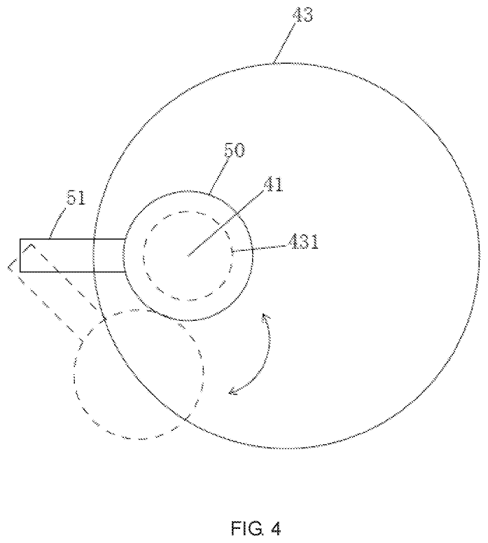

Specifically, as shown in FIG. 3 and FIG. 4, the evaporation device further includes an actuation mechanism 51 connected to the crystal shutter 50. The actuation mechanism 51 enables the crystal shutter 50 to revolve, so that the crystal shutter 50 switches between the position that the crystal vibrator 41 is shielded and the position that the crystal vibrator 41 is not shielded. Specifically, at least part of the actuation mechanism 51 is located within the crystal vibrator shielding cartridge 42.

The evaporation device of the disclosure configures the crystal shutter 50 between the evaporation source 20 and the crystal vibrator 41, and the crystal shutter 50 is capable of switching between the position that the crystal vibrator 41 is shielded and the position that the crystal vibrator 41 is not shielded; An evaporation material is deposited on the crystal shutter 50 when the crystal shutter 50 is at the position that the crystal vibrator 41 is shielded, thereby avoiding the evaporation material deposited on the crystal vibrator 41: the evaporation material may be deposited on the crystal vibrator 41 when the crystal shutter 50 is at the position that the crystal vibrator 41 is not shielded; when the evaporation device of the disclosure is applied to an evaporation process, at the initial stage of evaporation, namely the stage in which surface impurities of an material to be evaporated 215 are evaporated, the crystal shutter 50 is at the position that the crystal vibrator 41 is shielded and the impurities are prevented from being deposited on the surface of the crystal vibrator 41; after the evaporation of the surface impurities of the material to be evaporated 215 are finished, the crystal shutter 50 is at the position that the crystal vibrator 41 is not shielded, and the evaporation material is deposited on the surface of the crystal vibrator 41, and the evaporation rate monitoring device 40 obtains a steady evaporation rate, and the thickness of the target film layer 31 deposited on the film substrate to be evaporated 30 may be monitored according to the evaporation rate.

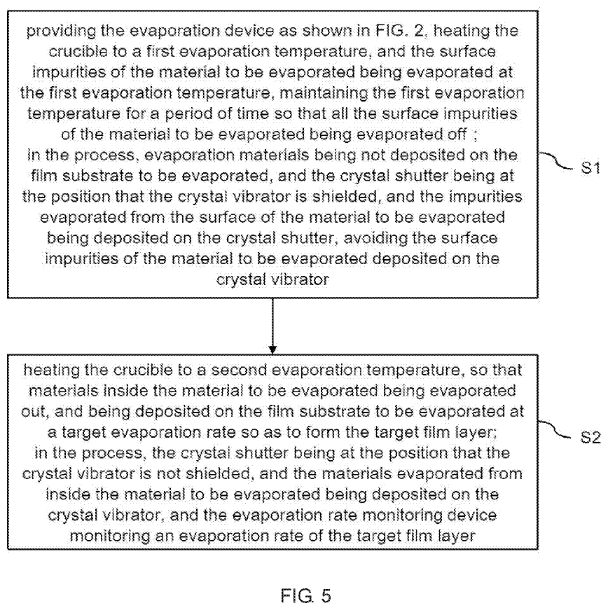

With reference to FIG. 5, and with reference to FIG. 2 to FIG. 4, based on the above evaporation device, the disclosure further provides an evaporation method, including the following steps:

step S1, as shown in FIG. 2 to FIG. 4, providing the above evaporation device, and in the evaporation device, the evaporation source 20 include a crucible 21 and the material to be evaporated 215 placed within the crucible 21, and the crucible 21 is heated to a first evaporation temperature, and the surface impurities of the material to be evaporated 215 may be evaporated at the first evaporation temperature;

the first evaporation temperature is maintained for a period of time so that all the surface impurities of the material to be evaporated 215 have been evaporated off;

in the step S1, the evaporation material is not deposited on the film substrate to be evaporated 30;

in the step S1, the crystal shutter 50 has been at the position that the crystal vibrator 41 is shielded, and the impurities evaporated from the surface of the material to be evaporated 215 are deposited on the crystal shutter 50, avoiding the surface impurities of the material to be evaporated 215 deposited on the crystal vibrator 41.

In the step S1, before heating the crucible 21, the chamber 10 is firstly evacuated to a desired degree of vacuum. Preferably, the desired degree of vacuum is E⁻⁵ Pa.

Specifically, the material to be evaporated 215 is an active metal material, and the surface impurities of the material to be evaporated 215 are oxides and/or nitrides of the active metal materials. The active metal materials include one or more of lithium (Li), potassium (K), calcium (Ca), magnesium (Mg), ytterbium (Yb) and barium (Ba).

When the material to be evaporated 215 is lithium (Li), its oxides and nitrides are lithium oxide (Li₂O) and lithium nitride (Li₃N), and at the moment, the first evaporation temperature is preferably 400, and the first evaporation temperature is preferably maintained for one hour.

Specifically, in the step S1, locating the source shutter 22 at the position that evaporation source 20 is shielded or the film substrate to be evaporated 30 not entering into the chamber 10 ensures that the surface impurities of the material to be evaporated 215 are not deposited on the film substrate to be evaporated 30.

Step S2, the crucible 21 is heated to a second evaporation temperature, and materials inside the material to be evaporated 215 may be evaporated out at the second evaporation temperature, and are deposited on the film substrate to be evaporated 30 at a target evaporation rate so as to form the target film layer 31.

In the step S2, the crystal shutter 50 has been at the position that the crystal vibrator 41 is not shielded, and the materials evaporated from inside the material to be evaporated 215 are deposited on the crystal vibrator 41, and the evaporation rate monitoring device 40 monitors an evaporation rate of material film layer deposited on the crystal vibrator 41 and calculates to obtain the evaporation rate of the target film layer 1 deposited on the film substrate to be evaporated 30.

In the step S2, since materials deposited on the crystal vibrator 41 have ultra purity and no impurities, the evaporation rate monitored by the evaporation rate monitoring device 40 is steady, and the thickness of the target film layer 31 may be monitored according to the evaporation rate.

When the material to be evaporated 215 is lithium (Li), the second evaporation temperature is preferably 300′C.

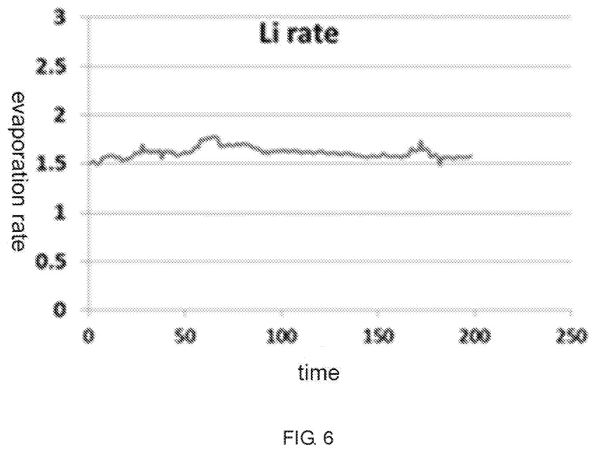

FIG. 6 is a curve of the evaporation rate monitored by the evaporation rate monitoring device in step S2 in the evaporation method of the disclosure. It can be seen from FIG. 6, the evaporation rate of the metal lithium (Li) is steady, and the monitoring effect of the evaporation rate is good.

The evaporation method of the disclosure may be achieved by the above evaporation device, and can ensure that influences of the surface impurities of the material to be evaporated 215 on the monitor of the evaporation rate can be avoided during an evaporation process, and allow the evaporation rate monitoring device 40 to obtain the steady evaporation rate, the thickness of the target film layer 31 deposited on the film substrate to be evaporated 30 may be real time and effectively monitored according to the evaporation rate.

It is worth mentioning that the wording “evaporation rate” in the disclosure is the abbreviation for “rate of evaporation”, and both “evaporation rate” and “rate of evaporation” refer to the deposition rate of film layers.

In summary, the disclosure provides an evaporation device and an evaporation method. The evaporation device of the disclosure configures an crystal shutter between an evaporation source and a crystal vibrator, and the crystal shutter is capable of switching between the position that the crystal vibrator is shielded and the position that the crystal vibrator is not shielded; an evaporation material is deposited on the crystal shutter when the crystal shutter is at the position that the crystal vibrator is shielded, thereby avoiding the evaporation material deposited on the crystal vibrator; the evaporation material may be deposited on the crystal vibrator when the crystal shutter is at the position that the crystal vibrator is not shielded; when the evaporation device of the disclosure is applied to an evaporation process, at the initial stage of evaporation, namely the stage in which surface impurities of an material to be evaporated are evaporated, the crystal shutter is at the position that the crystal vibrator is shielded and the impurities are prevented from being deposited on the surface of the crystal vibrator; after the evaporation of the surface impurities of the material to be evaporated are finished, the crystal shutter is at the position that the crystal vibrator is not shielded, and the evaporation material is deposited on the surface of the crystal vibrator, and the evaporation rate monitoring device obtains a steady evaporation rate, and the thickness of a target film layer deposited on the film substrate to be evaporated may be monitored according to the evaporation rate. The evaporation method of the disclosure may be achieved by the above evaporation device, and can ensure that influences of the surface impurities of the material to be evaporated on the monitor of an evaporation rate can be avoided during an evaporation process, and allow the evaporation rate monitoring device to obtain the steady evaporation rate, and the thickness of the target film layer deposited on the film substrate to be evaporated may be real time and effectively monitored according to the evaporation rate.

As for the above, various corresponding modifications and alterations may be made by a person skilled in the art according to the technical solution and technical idea of the disclosure, and all these modifications and alterations shall fall within the scope of protection of the claims of the disclosure.

What is claimed is:

1. An evaporation device, comprising: a chamber, an evaporation source disposed in the chamber, a film substrate to be evaporated disposed in the chamber and located over the evaporation source, and an evaporation rate monitoring device disposed in the chamber and located over the evaporation source;
the evaporation rate monitoring device comprises a crystal vibrator; and the crystal vibrator is a probe of the evaporation rate monitoring device, and the evaporation rate monitoring device monitors evaporation rate of a material film layer deposited on the crystal vibrator and then calculates so as to obtain the evaporation rate of a target film layer deposited on the film substrate to be evaporated;
the evaporation device further comprises a crystal shutter disposed at any positions between the evaporation source and the crystal vibrator, and the crystal shutter is capable of switching between the position that the crystal vibrator is shielded and the position that the crystal vibrator is not shielded.

2. The evaporation device according to claim 1, further comprising a source shutter disposed over the evaporation source, and the source shutter being capable of switching between the position that the evaporation source is shielded and the position that the evaporation source is not shielded;
the evaporation source comprising a crucible and a material to be evaporated placed within the crucible;
the crystal vibrator being quartz crystal vibrator;
the crystal shutter being located close to the crystal vibrator between the evaporation source and the crystal vibrator, close to the evaporation source between the evaporation source and the crystal vibrator, or in the middle position between the crystal vibrator and the evaporation source.

3. The evaporation device according to claim 2, wherein the crystal shutter is located close to the crystal vibrator between the evaporation source and the crystal vibrator.

4. The evaporation device according to claim 1, wherein the diameter of the crystal shutter of the crystal vibrator is greater than the diameter of an area of the film to be evaporated of the crystal vibrator.

5. The evaporation device according to claim 1, wherein the crystal shutter is made of metal materials, and the metal materials comprise one or more of stainless steel, aluminum, and titanium.

6. The evaporation device according to claim 1, wherein the crystal shutter has a surface roughening treated surface disposed at one side facing the evaporation source, and the surface roughening treatment comprises one or more of shot peening, sand blasting, and aluminum spray treatment.

7. The evaporation device according to claim 3, wherein the specific structure of the evaporation rate monitoring device comprises: a crystal vibrator shielding cartridge, a crystal vibrator base sleeve disposed in the crystal vibrator shielding cartridge, a crystal vibrator base disposed in the crystal vibrator base sleeve, and a plurality of the crystal vibrators mounted on the crystal vibrator base, and an opening is disposed on the crystal vibrator base sleeve, and the crystal vibrators being used are present at the opening of the crystal vibrator base sleeve, and the crystal vibrators not being used are absent from the opening, and the crystal vibrator being used is switched to another crystal vibrator until the end of its service life;
the crystal shutter is located within the crystal vibrator shielding cartridge;
the crystal shutter locating at the position that the crystal vibrator is shielded means that the crystal shutter is located at the opening and shields the crystal vibrator being used; the crystal shutter locating at the position that the crystal vibrator is not shielded means that the crystal shutter is not located at the opening and does not shield the crystal vibrator being used.

8. The evaporation device according to claim 1, further comprising an actuation mechanism connected to the crystal shutter; the actuation mechanism enabling the crystal shutter to revolve, so that the crystal shutter switches between the position that the crystal vibrator is shielded and the position that the crystal vibrator is not shielded.

9. An evaporation method, comprising the following steps:
step S1, providing the evaporation device according to claim 1, and in the evaporation device, the evaporation source comprising a crucible and a material to be evaporated placed within the crucible, and heating the crucible to a first evaporation temperature, and the surface impurities of the material to be evaporated being evaporated at the first evaporation temperature;
maintaining the first evaporation temperature for a period of time so that all the surface impurities of the material to be evaporated being evaporated off;
in the step S1, evaporation materials being not deposited on the film substrate to be evaporated;
and, in the step S1, the crystal shutter being at the position that the crystal vibrator is shielded, and the impurities evaporated from the surface of the material to be evaporated being deposited on the crystal shutter, avoiding the surface impurities of the material to be evaporated deposited on the crystal vibrator;
Step S2, heating the crucible to a second evaporation temperature, and materials inside the material to be evaporated being evaporated out at the second evaporation temperature, and being deposited on the film substrate to be evaporated at a target evaporation rate so as to form the target film layer;
in the step S2, the crystal shutter being at the position that the crystal vibrator is not shielded, and the materials evaporated from inside the material to be evaporated being deposited on the crystal vibrator, and the evaporation rate monitoring device monitoring an evaporation rate of a material film layer deposited on the crystal vibrator and calculating to obtain the evaporation rate of the target film layer deposited on the film substrate to be evaporated.

10. The evaporation method according to claim 9, wherein in the step S1, before heating the crucible, the chamber is firstly evacuated to a desired degree of vacuum; the material to be evaporated is active metal materials, and the surface impurities of the material to be evaporated are oxides and/or nitrides of the active metal materials; the active metal materials comprise one or more of lithium, potassium, calcium, magnesium, ytterbium and barium.

11. An evaporation device, comprising: a chamber, an evaporation source disposed in the chamber, a film substrate to be evaporated disposed in the chamber and located over the evaporation source, and an evaporation rate monitoring device disposed in the chamber and located over the evaporation source;
the evaporation rate monitoring device comprises a crystal vibrator; and the crystal vibrator being a probe of the evaporation rate monitoring device, and the evaporation rate monitoring device monitoring evaporation rate of a material film layer deposited on the crystal vibrator and then calculating so as to obtain the evaporation rate of a target film layer deposited on the film substrate to be evaporated;
the evaporation device further comprising a crystal shutter disposed at any positions between the evaporation source and the crystal vibrator, and the crystal shutter being capable of switching between the position that the crystal vibrator is shielded and the position that the crystal vibrator is not shielded;
further comprising a source shutter disposed over the evaporation source, and the source shutter being capable of switching between the position that the evaporation source is shielded and the position that the evaporation source is not shielded;
the evaporation source comprising a crucible and a material to be evaporated placed within the crucible;
the crystal vibrator being quartz crystal vibrator;
the crystal shutter being located close to the crystal vibrator between the evaporation source and the crystal vibrator, close to the evaporation source between the evaporation source and the crystal vibrator, or in the middle position between the crystal vibrator and the evaporation source;
wherein the diameter of the crystal shutter of the crystal vibrator is greater than the diameter of an area of the film to be evaporated of the crystal vibrator;
wherein the crystal shutter is made of metal materials, and the metal materials comprise one or more of stainless steel, aluminum, and titanium;
wherein the crystal shutter has a surface roughening treated surface disposed at one side facing the evaporation source, and the surface roughening treatment comprises one or more of shot peening, sand blasting, and aluminum spray treatment.

12. The evaporation device according to claim 11, wherein the crystal shutter is located close to the crystal vibrator between the evaporation source and the crystal vibrator.

13. The evaporation device according to claim 12, wherein the specific structure of the evaporation rate monitoring device comprises: a crystal vibrator shielding cartridge, a crystal vibrator base sleeve disposed in the crystal vibrator shielding cartridge, a crystal vibrator base disposed in the crystal vibrator base sleeve, and a plurality of the crystal vibrators mounted on the crystal vibrator base, and an opening is disposed on the crystal vibrator base sleeve, and the crystal vibrators being used are present at the opening of the crystal vibrator base sleeve, and the crystal vibrators not being used are absent from the opening, and the crystal vibrator being used is switched to another crystal vibrator until the end of its service life;
the crystal shutter is located within the crystal vibrator shielding cartridge;
the crystal shutter locating at the position that the crystal vibrator is shielded means that the crystal shutter is located at the opening and shields the crystal vibrator being used; the crystal shutter locating at the position that the crystal vibrator is not shielded means that the crystal shutter is not located at the opening and does not shield the crystal vibrator being used.

14. The evaporation device according to claim 11, further comprising an actuation mechanism connected to the crystal shutter; the actuation mechanism enabling the crystal shutter to revolve, so that the crystal shutter switches between the position that the crystal vibrator is shielded and the position that the crystal vibrator is not shielded.
